(19) United States
(12) Patent Application Publication
(10) Pub. No.: US 2021/0325747 A1
(43) Pub. Date: Oct. 21, 2021

(54) LIQUID CRYSTAL DISPLAY DEVICE

(71) Applicant: Shenzhen China Star Optoelectronics Semiconductor Display Technology Co., Ltd., Shenzhen (CN)

(72) Inventor: Jiangchuan CHEN, Shenzhen (CN)

(73) Assignee: Shenzhen China Star Optoelectronics Semiconductor Display Technology Co., Ltd., Shenzhen (CN)

(21) Appl. No.: 16/627,308

(22) PCT Filed: Dec. 19, 2019
(86) PCT No.: PCT/CN2019/126657

§ 371 Date: Dec. 29, 2019

(30) Foreign Application Priority Data
Dec. 12, 2019 (CN) 201911271993.5

(51) Int. Cl. G02F 1/1362; G02F 1/1368

(52) U.S. Cl. CPC G02F 1/136286; G02F 1/136222; G02F 1/1368

(57) ABSTRACT

A liquid crystal display device is provided. An overlapping area of source/drain with respect to an active layer of a thin film transistor of adjacent sub-pixels is consistent, so that a gate-source capacitance of the adjacent sub-pixels is consistent, which can avoid the problems of uneven display and display difference caused by the feedthrough voltage difference induced by the gate-source capacitance inconsistencies, and improve the picture quality of dual-gate products.

### FIELD OF INVENTION

The present disclosure relates to a liquid crystal display device, and more particularly to a liquid crystal display device configured to a dual gate driving method.

### BACKGROUND OF INVENTION

Present driving circuits include single gate drive and dual gate drive. In a thin film transistor (TFT) substrate structure of a single gate drive, the distribution and connection of TFTs with data lines and gate lines are a sub-pixel corresponding to a gate line 160. Another type of dual gate drive is to double the gate lines and halve the data lines, in which adjacent TFTs, that is, sources of adjacent sub-pixels are connected to a same data line, but gates of adjacent sub-pixels are respectively connected to different gate lines, and the TFT opening directions of adjacent sub-pixels are different.

In the manufacturing process, due to process deviations such as exposure and development, an overlapping area of the source/drain with respect to an active layer of the adjacent TFTs will be inconsistent, resulting in inconsistent gate-source capacitances (Cgs) of the adjacent sub-pixels, which in turn leads to a feedthrough voltage differences and causes problems such as display unevenness and display differences. Especially for products with low pixel density (pixels per inch, PPI), the transmittance of adjacent pixels on the left and right will vary in the visibility of human eyes. For example, in a car display, this problem will be so serious that vertical lines can be seen.

At present, the way to solve the inconsistency between the gate-source capacitance (Cgs) is to use a compensation circuit to compensate the gate-source capacitance (Cgs).

Technical problem

The sources of TFTs of adjacent sub-pixels in a dual gate drive are connected to a same data line, but the gates of adjacent sub-pixels are connected to different gate lines respectively, which forms TFT opening direction of adjacent sub-pixels is different. An overlapping area of the source/drain with respect to an active layer of the adjacent TFTs will be inconsistent, resulting in inconsistent gate-source capacitances (Cgs) of the adjacent sub-pixels, which in turn leads to a feedthrough voltage differences and causes problems such as display unevenness and display differences.

### SUMMARY OF INVENTION

### Technical Solutions

The main purpose of the present application is that a thin film transistor (TFT) substrate structure for a dual-gate driving circuit does not need to do gate-source capacitance (Cgs) compensation. For the purpose of eliminating the need for Cgs compensation, the present application proposes a liquid crystal display device in which an overlapping area of source/drain with respect to an active layer of a thin film transistor of the adjacent sub-pixels is consistent, so that the gate-source capacitance (Cgs) of the adjacent sub-pixels is same. Therefore, it can avoid the problems of uneven display and display difference caused by the feedthrough voltage difference induced by the gate-source capacitance (Cgs) inconsistencies, and improve the picture quality of dual-gate products.

The liquid crystal display device provided by the present application, including a plurality of scan lines, a plurality of data lines perpendicular to the scan lines, and a plurality of sub-pixels defined by the scan lines and the data lines, wherein each of the sub-pixels includes a thin film transistor, the thin film transistor includes a gate, a source, and a drain, the gate is correspondingly connected to one of the scan lines, each of the data lines includes two extending portions corresponding to each of the thin film transistors, the two extending portions are configured to form two branches of the source, an end of the drain faces an opening defined by the two branches, and the openings of the sub-pixels are arranged toward a same direction.

In an embodiment, the sub-pixels in a same column are connected to a same data line.

In an embodiment, further including a data driving chip disposed in a non-display region, and a fanout region connected between the data driving chip and the data lines, wherein a plurality of traces of the fanout region are connected to the data driving chip, and each two of the data lines are correspondingly connected to one of the traces of the fanout region.

In an embodiment, the adjacent sub-pixels are connected to different scan lines.

In an embodiment, further including a gate driving chip disposed in a non-display region, and a gate driving fanout region connected between the gate driving chip and the scan lines, wherein a plurality of traces of the gate driving fanout region are connected to the gate driving chip, and each of the scan lines is correspondingly connected to one of the traces of the gate driving fanout region.

In an embodiment, the two extending portions of the data line have a symmetrical structure based on a symmetry axis, and the symmetry axis is parallel to the scan lines.

In an embodiment, the thin film transistor further includes a gate insulating layer and an active layer laminated above the gate, a planarization layer covering the active layer, the source, and the drain, and an upper electrode disposed on the planarization layer, wherein the sub-pixel further includes a lower electrode, and a part of the drain is electrically connected to the lower electrode.

In an embodiment, the upper electrode has a strip shape and is disposed corresponding to the lower electrode to form a fringe field switching electrode structure.

In an embodiment, the liquid crystal display device further including a color filter substrate, a liquid crystal layer, and a first alignment film positioned between the upper electrode and the liquid crystal layer.

In an embodiment, the sub-pixels include red sub-pixels, green sub-pixels, and blue sub-pixels, or the plurality of sub-pixels include red sub-pixels, green sub-pixels, blue sub-pixels, and white sub-pixels.

The present application also provides a liquid crystal display device, including a plurality of scan lines, a plurality of data lines perpendicular to the scan lines, and a plurality of sub-pixels defined by the scan lines and the data lines, wherein each of the sub-pixels includes a thin film transistor, the thin film transistor includes a gate, a source, and a drain, the gate is correspondingly connected to one of the scan lines, each of the data lines includes two extending portions corresponding to each of the thin film transistors, the two extending portions are configured to form two branches of the source, an end of the drain faces an opening defined by the two branches, and the openings of the sub-pixels are arranged toward a same direction, wherein further includes a data driving chip disposed in a non-display region, and a fanout region connected between the data driving chip and the data lines, wherein a plurality of traces of the fanout region are connected to the data driving chip, and each two of the data lines are correspondingly connected to one of the traces of the fanout region.

In an embodiment, the sub-pixels in a same column are connected to a same data line.

In an embodiment, the adjacent sub-pixels are connected to different scan lines.

In an embodiment, further including a gate driving chip disposed in the non-display region, and a gate driving fanout region connected between the gate driving chip and the scan lines, wherein a plurality of traces of the gate driving fanout region are connected to the gate driving chip, and each of the scan lines is correspondingly connected to one of the traces of the gate driving fanout region.

In an embodiment, the two extending portions of the data line have a symmetrical structure based on a symmetry axis, and the symmetry axis is parallel to the scan lines.

In an embodiment, the thin film transistor further includes a gate insulating layer and an active layer laminated above the gate, a planarization layer covering the active layer, the source, and the drain, and an upper electrode disposed on the planarization layer, wherein the sub-pixel further includes a lower electrode, and a part of the drain is electrically connected to the lower electrode.

In an embodiment, the upper electrode has a strip shape and is disposed corresponding to the lower electrode to form a fringe field switching electrode structure.

In an embodiment, the liquid crystal display device further including a color filter substrate, a liquid crystal layer, and a first alignment film positioned between the upper electrode and the liquid crystal layer.

In an embodiment, the sub-pixels include red sub-pixels, green sub-pixels, and blue sub-pixels, or the sub-pixels include red sub-pixels, green sub-pixels, blue sub-pixels, and white sub-pixels.

The present application further provides a liquid crystal display device, including a plurality of scan lines, a plurality of data lines perpendicular to the scan lines, and a plurality of sub-pixels defined by the scan lines and the data lines, wherein each of the sub-pixels includes a thin film transistor, the thin film transistor includes a gate, a source, and a drain, the gate is correspondingly connected to one of the scan lines, each of the data lines includes two extending portions corresponding to each of the thin film transistors, the two extending portions are configured to form two branches of the source, an end of the drain faces an opening defined by the two branches, and the openings of the sub-pixels are arranged toward a same direction; wherein the liquid crystal display device further includes a data driving chip disposed in a non-display region, and a fanout region connected between the data driving chip and the data lines, wherein a plurality of traces of the fanout region are connected to the data driving chip, and each two of the data lines are correspondingly connected to one of the traces of the fanout region; and a gate driving chip disposed in the non-display region, and a gate driving fanout region connected between the gate driving chip and the scan lines, wherein a plurality of traces of the gate driving fanout region are connected to the gate driving chip, and each of the scan lines is correspondingly connected to one of the traces of the gate driving fanout region.

Beneficial Effect

The present application proposes a liquid crystal display device. For the purpose of not requiring gate-source capacitance (Cgs) compensation, adjacent sub-pixels are connected to different scan lines, so that left and right sub-pixels are controlled separately. Moreover, a data line inputted to a display region is divided into two, the TFT opening directions of adjacent sub-pixels can be made same, which effectively avoids realistic vertical lines or other image quality problems caused by the feedthrough voltage difference of the adjacent sub-pixels induced by the gate-source capacitance (Cgs) of the adjacent sub-pixels inconsistencies that an overlapping area of source/drain with respect to an active layer of the TFT of the adjacent sub-pixels is inconsistent, thereby improving the display image quality.

### BRIEF DESCRIPTION OF FIGURES

In order to illustrate the technical solutions of the present disclosure or the related art in a clearer manner, the drawings desired for the present disclosure or the related art will be described hereinafter briefly.

Obviously, the following drawings merely relate to some embodiments of the present disclosure, and based on these drawings, a person skilled in the art may obtain the other drawings without any creative effort.

FIG. 1 is a schematic diagram of a dual gate driving circuit of a liquid crystal display device according to an embodiment of the present invention.

FIG. 2 is a schematic cross-sectional view taken along a line A-A′ in FIG. 1.

### DETAILED DESCRIPTION OF EMBODIMENTS

The following description of each embodiment, with reference to the accompanying drawings, is used to exemplify specific embodiments which may be carried out in the present invention. Directional terms mentioned in the present invention, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present invention. In the drawings, components having similar structures are denoted by the same numerals.

The present application proposes a liquid crystal display device. For the purpose of not requiring gate-source capacitance (Cgs) compensation, adjacent sub-pixels are connected to different scan lines, so that left and right sub-pixels are controlled separately, moreover, a data line inputted to a display region is divided into two, thin film transistor (TFT) opening directions of adjacent sub-pixels can be made same, which effectively avoids realistic vertical lines or other image quality problems caused by the feedthrough voltage difference of the adjacent sub-pixels induced by the gate-source capacitance (Cgs) of the adjacent sub-pixels inconsistencies that an overlapping area of source/drain with respect to an active layer of the TFT of the adjacent sub-pixels is inconsistent, thereby improving the display image quality. Specific embodiments are described below.

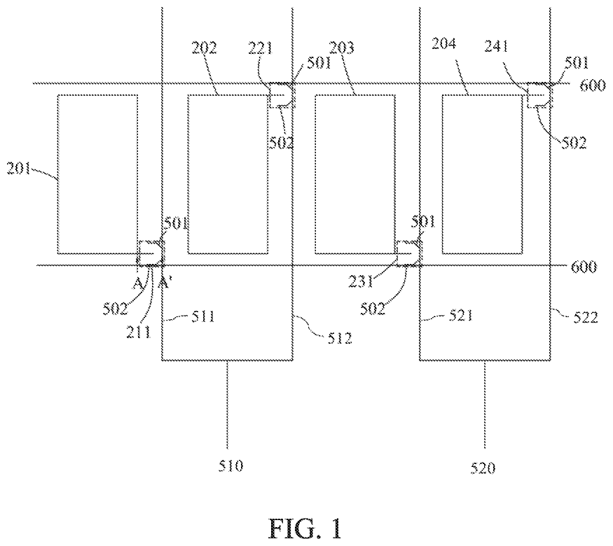

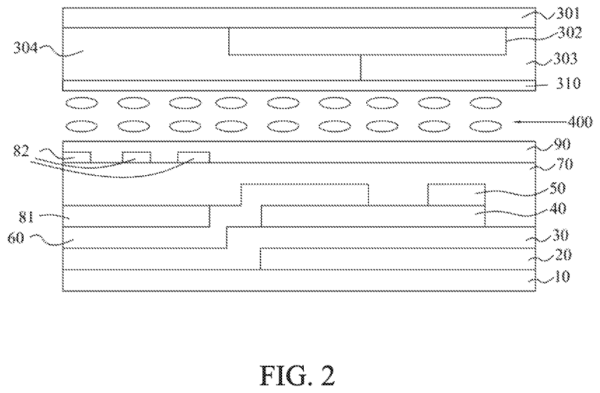

For an embodiment provided in the present application, please refer to FIG. 1 and FIG. 2, where FIG. 1 is a schematic diagram of a dual gate driving circuit according to an embodiment of the present invention and FIG. 2 is a schematic cross-sectional view taken along a line A-A′ in FIG. 1. The liquid crystal display device includes a data driving chip disposed in a non-display region, and a fanout region connected between the data driving chip and a plurality of data lines. A plurality of traces of the fanout region are connected to the data driving chip, and each two of the data lines are correspondingly connected to one of the traces of the fanout region. In other words, the fanout region of the driving chip (IC) maintains a dual gate architecture that number of data lines halved, but the data line is divided into two when entering the display region. For example, as shown in FIG. 1, a data line 510 is divided into a data line 511 and a data line 512, and a data line 520 is divided into a data line 521 and a data line 522 when entering the display region.

The liquid crystal display device proposed in the present application includes a plurality of scan lines 600, a plurality of data lines 511, 512, 521, 522 that are perpendicular to the plurality of scan lines, and a plurality of sub-pixels 201, 202, 203, and 204 defined by the plurality of scan lines and the plurality of data lines. Each sub-pixel includes a thin film transistor (TFT) 211, 221, 231, or 241. The TFT includes a gate 20, a gate insulating layer 30, an active layer 40, a source 50 and a drain 60, and a planarization layer 70 that are sequentially stacked on a substrate 10. The gate 20 is correspondingly connected to one of the scan lines 600. Each of the data lines includes two extending portions corresponding to each of the TFTs, the two extending portions are configured to form two branches of the source 50, an end of the drain 60 faces an opening defined by the two branches 501, 502, and the openings of the sub-pixels are arranged toward a same direction.

As shown in FIG. 1, for example, the sub-pixel 201, the sub-pixel 202, and the sub-pixel 203 form a pixel unit, and corresponding to a red sub-pixel, a green sub-pixel, and a blue sub-pixel in a color filter, respectively, and the sub-pixel 204 corresponds to a red sub-pixel in an adjacent pixel unit. Adjacent sub-pixels are connected to different scan lines, a TFT 211 of sub-pixel 201 is connected to data line 511, and a TFT 221 of sub-pixel 202 is connected to data line 512. The data line 520 is divided into the data line 521 and the data line 522 when entering the display region, and a TFT 231 of the sub-pixel 203 is connected to the data line 521 and a TFT 241 of the sub-pixel 204 is connected to the data line 522. Thus, the left and right data lines 510 and 520 control corresponding adjacent sub-pixels 201, 202, 203, and 204, respectively.

Based on the abovementioned, all the sub-pixels in a same column are connected to a same data line 511, 521, that is, the two branches 501, 502 of each TFT of all the sub-pixels in same column are positioned on a same side of the same data line. In this way, based on each opening of each the sub-pixel is arranged toward the same direction, furthermore, the left and right data lines 510 and 520 control the adjacent sub-pixels 201, 202, 203, and 204, respectively, an overlapping area of source/drain with respect to the active layer of the TFT of the adjacent sub-pixels, even if there is a deviation caused by process alignment, the gate-source capacitance (Cgs) of each TFT is maintained because of a same deviation. Therefore, the solution of the present invention does not need to do Cgs compensation. In addition, Cgs is based on design requirements, the two extending portions 501, 502 of the data line have a symmetrical structure based on a symmetry axis, and the symmetry axis is parallel to the scan lines.

The liquid crystal display device further includes a gate driving chip disposed in a non-display region, and a gate driving fanout region connected between the gate driving chip and the scan lines. A plurality of traces of the gate driving fanout region are connected to the gate driving chip, and each of the scan lines is correspondingly connected to one of the traces of the gate driving fanout region.

The liquid crystal display device further includes an upper electrode disposed above the planarization layer 70, each sub-pixel further includes a lower electrode 81, and a portion of the drain 60 is electrically connected to the lower electrode 81. In one embodiment, when the upper electrode 82 has a strip shape and is disposed corresponding to the lower electrode 81 to form a fringe field switching (FFS) electrode structure.

The liquid crystal display device can further includes a color filter substrate 300, a liquid crystal layer 400, and a first alignment film 90 disposed between the upper electrode and the liquid crystal layer. The color filter substrate 300 includes at least a substrate 301, color photoresists 303, 304, a black matrix 302 positioned between different color photoresists, and a second alignment film 310 positioned between the color photoresists and the liquid crystal layer.

The plurality of sub-pixels defined by the plurality of scan lines and the plurality of data lines corresponding to different color photoresistors on the color filter substrate 300 can be designed to include red sub-pixels, green sub-pixels, and blue sub-pixels, or the plurality of sub-pixels including red sub-pixels, green sub-pixels, blue sub-pixels, and white sub-pixels.

In addition, in the conventional thin-film transistor design scheme configured to a dual gate driving method, the transmittance design value can be adjusted to be consistent from left to right, due to process deviations, when there is a certain misalignment in the black matrix (BM), it is difficult to have no misalignment at all. However, in the present application, in addition to the above-mentioned adjacent sub-pixels connected to different scan lines to control the left and right sub-pixels separately, the present application also divides the data line into two when the data line is inputted into the display region, which can make the source of TFT of all the sub-pixels has symmetry in a X direction, that is, the two extending portions connected to the data line have a symmetrical structure in which the axis of symmetry is parallel to the scan line. Therefore, the solution of the present invention does not require Cgs compensation. Furthermore, it is convenient to design and manufacture, and the difference in transmittance between the left and right sub-pixels can be less than a degree of visibility by the human eye.

Embodiments of the present invention have been described, but not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A liquid crystal display device, comprising a plurality of scan lines, a plurality of data lines perpendicular to the scan lines, and a plurality of sub-pixels defined by the scan lines and the data lines, wherein each of the sub-pixels comprises a thin film transistor, the thin film transistor comprises a gate, a source, and a drain, the gate is correspondingly connected to one of the scan lines, each of the data lines comprises two extending portions corresponding to each of the thin film transistors, the two extending portions are configured to form two branches of the source, an end of the drain faces an opening defined by the two branches, and the openings of the sub-pixels are arranged toward a same direction.

2. The liquid crystal display device according to claim 1, wherein the sub-pixels in a same column are connected to a same data line.

3. The liquid crystal display device according to claim 2, further comprising a data driving chip disposed in a non-display region, and a fanout region connected between the data driving chip and the data lines, wherein a plurality of traces of the fanout region are connected to the data driving chip, and each two of the data lines are correspondingly connected to one of the traces of the fanout region.

4. The liquid crystal display device according to claim 1, wherein the adjacent sub-pixels are connected to different scan lines.

5. The liquid crystal display device according to claim 4, further comprising a gate driving chip disposed in a non-display region, and a gate driving fanout region connected between the gate driving chip and the scan lines, wherein a plurality of traces of the gate driving fanout region are connected to the gate driving chip, and each of the scan lines is correspondingly connected to one of the traces of the gate driving fanout region.

6. The liquid crystal display device according to claim 1, wherein the two extending portions of the data line have a symmetrical structure based on a symmetry axis, and the symmetry axis is parallel to the scan lines.

7. The liquid crystal display device according to claim 1, wherein the thin film transistor further comprises a gate insulating layer and an active layer laminated above the gate, a planarization layer covering the active layer, the source, and the drain, and an upper electrode disposed on the planarization layer, wherein the sub-pixel further comprises a lower electrode, and a part of the drain is electrically connected to the lower electrode.

8. The liquid crystal display device according to claim 7, wherein the upper electrode has a strip shape and is disposed corresponding to the lower electrode to form a fringe field switching electrode structure.

9. The liquid crystal display device according to claim 7, further comprising a color filter substrate, a liquid crystal layer, and a first alignment film positioned between the upper electrode and the liquid crystal layer.

10. The liquid crystal display device according to claim 9, wherein the sub-pixels comprise red sub-pixels, green sub-pixels, and blue sub-pixels, or the plurality of sub-pixels comprise red sub-pixels, green sub-pixels, blue sub-pixels, and white sub-pixels.

11. A liquid crystal display device, comprising a plurality of scan lines, a plurality of data lines perpendicular to the scan lines, and a plurality of sub-pixels defined by the scan lines and the data lines, wherein each of the sub-pixels comprises a thin film transistor, the thin film transistor comprises a gate, a source, and a drain, the gate is correspondingly connected to one of the scan lines, each of the data lines comprises two extending portions corresponding to each of the thin film transistors, the two extending portions are configured to form two branches of the source, an end of the drain faces an opening defined by the two branches, and the openings of the sub-pixels are arranged toward a same direction, wherein further comprises a data driving chip disposed in a non-display region, and a fanout region connected between the data driving chip and the data lines, wherein a plurality of traces of the fanout region are connected to the data driving chip, and each two of the data lines are correspondingly connected to one of the traces of the fanout region.

12. The liquid crystal display device according to claim 11, wherein the sub-pixels in a same column are connected to a same data line.

13. The liquid crystal display device according to claim 11, wherein the adjacent sub-pixels are connected to different scan lines.

14. The liquid crystal display device according to claim 13, further comprising a gate driving chip disposed in the non-display region, and a gate driving fanout region connected between the gate driving chip and the scan lines, wherein a plurality of traces of the gate driving fanout region are connected to the gate driving chip, and each of the scan lines is correspondingly connected to one of the traces of the gate driving fanout region.

15. The liquid crystal display device according to claim 11, wherein the two extending portions of the data line have a symmetrical structure based on a symmetry axis, and the symmetry axis is parallel to the scan lines.

16. The liquid crystal display device according to claim 11, wherein the thin film transistor further comprises a gate insulating layer and an active layer laminated above the gate, a planarization layer covering the active layer, the source, and the drain, and an upper electrode disposed on the planarization layer, wherein the sub-pixel further comprises a lower electrode, and a part of the drain is electrically connected to the lower electrode.

17. The liquid crystal display device according to claim 16, wherein the upper electrode has a strip shape and is disposed corresponding to the lower electrode to form a fringe field switching electrode structure.

18. The liquid crystal display device according to claim 16, further comprising a color filter substrate, a liquid crystal layer, and a first alignment film positioned between the upper electrode and the liquid crystal layer.

19. The liquid crystal display device according to claim 18, wherein the sub-pixels comprise red sub-pixels, green sub-pixels, and blue sub-pixels, or the sub-pixels comprise red sub-pixels, green sub-pixels, blue sub-pixels, and white sub-pixels.

20. A liquid crystal display device, comprising a plurality of scan lines, a plurality of data lines perpendicular to the scan lines, and a plurality of sub-pixels defined by the scan lines and the data lines, wherein each of the sub-pixels comprises a thin film transistor, the thin film transistor comprises a gate, a source, and a drain, the gate is correspondingly connected to one of the scan lines, each of the data lines comprises two extending portions corresponding to each of the thin film transistors, the two extending portions are configured to form two branches of the source, an end of the drain faces an opening defined by the two branches, and the openings of the sub-pixels are arranged toward a same direction; wherein the liquid crystal display device further comprises a data driving chip disposed in a non-display region, and a fanout region connected between the data driving chip and the data lines, wherein a plurality of traces of the fanout region are connected to the data driving chip, and each two of the data lines are correspondingly connected to one of the traces of the fanout region; and a gate driving chip disposed in the non-display region, and a gate driving fanout region connected between the gate driving chip and the scan lines, wherein a plurality of traces of the gate driving fanout region are connected to the gate driving chip, and each of the scan lines is correspondingly connected to one of the traces of the gate driving fanout region.
